(19) United States
(12) Patent Application Publication
(10) Pub. No.: US 2010/0047722 A1
(43) Pub. Date: Feb. 25, 2010

(54) THREE-DIMENSIONAL NANO MATERIAL STRUCTURES

(75) Inventor: Youngtack SHIM, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SEOUL NATIONAL UNIVERSITY RESEARCH & DEVELOPMENT BUSINESS FOUNDATION (SNU R&DB FOUNDATION), Seoul (KR)

(21) Appl. No.: 12/198,019

(22) Filed: Aug. 25, 2008

(51) Int. Cl. G03F 7/20

(52) U.S. Cl. 430/323; 430/322; 430/324

(57) ABSTRACT

Techniques for manufacturing a 3-D structure of nano materials are provided. In one embodiment, a method of manufacturing a 3-D structure of nano materials resembling a target structure comprises providing a substrate, and for each segment, forming a mask layer, and patterning the mask layer to form one or more grooves, and filling the grooves with the nano materials. The grooves correspond to one of the horizontal segments of the 3-D structure to be assembled. The method also comprises removing the mask layers.

### BACKGROUND

One of the principal themes in the nanotechnology field is the development of nano materials on an atomic or molecular scale (i.e., smaller than a micron). New or preeminent properties of nano materials are attributed to their nanoscale size. That is, when particles are reduced to nanoscale dimensions, their fundamental properties such as electrical conductivity, mechanical strength and melting point are all subject to change—often bringing dramatic improvements in performance, useful for various applications. For example, an opaque substance of macroscale may become a transparent substance of nanoscale; a stable substance of macroscale may turn into a combustible substance of nanoscale; a solid substance of macroscale may be converted into a liquid substance of nanoscale at room temperature; and an insulator of macroscale may become a conductor of nanoscale. Due to such novel properties, nano materials have been widely used in various fields.

However, despite their superior mechanical, chemical and electrical properties, there have been certain drawbacks in exploiting nano materials due to the difficulty of precisely arranging such small materials in useful structures. To more fully utilize and apply the preeminent properties of nano materials in various fields, it is necessary to conceive reliable arrangement mechanisms for fabricating 3-dimensional (“3-D”) nano material structures.

### SUMMARY

The present disclosure provides techniques for fabricating 3-D structures of nano materials using layer-by-layer construction. In one embodiment, a method for manufacturing a 3-D structure of nano materials comprises providing a substrate; forming a mask layer over the substrate; patterning a mask layer to form one or more grooves, wherein the grooves correspond to one of multiple horizontal segments of the 3-D structure; filling the grooves with the nano materials; repeating the above steps for the remaining horizontal segments; and removing the mask layers.

This Summary is provided to introduce a selection of concepts in a simplified form that are further described below in the Detailed Description. The Summary is not intended to identify key features or essential features of the claimed subject matter, nor is it intended to be used to limit the scope of the claimed subject matter.

### BRIEF DESCRIPTION OF THE DRAWINGS

FIGS. 1A and 1B show schematic diagrams illustrating exemplary 3-D structures of nano materials;

FIGS. 2A to 2R collectively show a process of fabricating an exemplary 3-D structure of nano materials in accordance with one embodiment; and

FIGS. 3A to 3S collectively show a process of fabricating an exemplary 3-D structure of nano materials in accordance with another embodiment.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and made part of this disclosure.

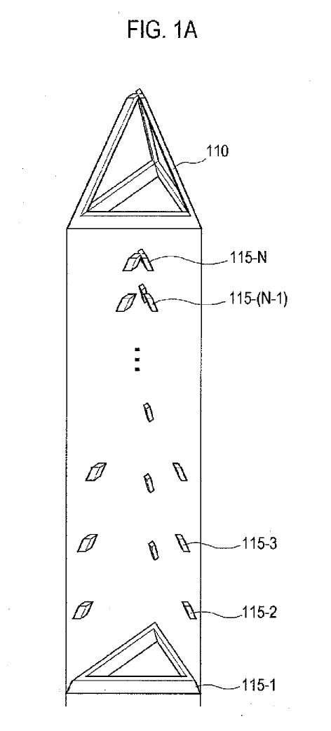

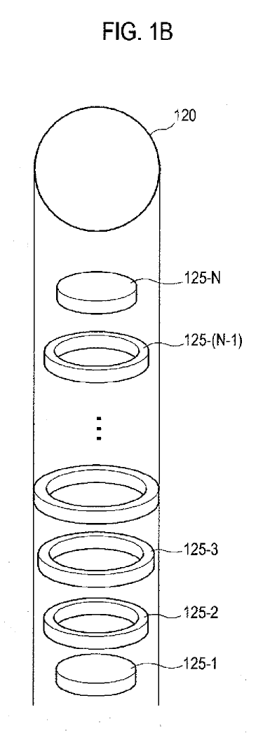

Exemplary 3-D structures of nano materials are illustrated in FIGS. 1A and 1B. A 3-D structure may be composed of multiple horizontal segments (or layers), which are formed of the same or different nano materials (such as carbon nanotubes or nanowires). The horizontal segments are stacked one over another in a layered configuration to form a 3-D structure of a desired shape and size. The number of horizontal segments can be determined based on, for example, the overall height of the desired configuration and/or the thickness of each segment. The greater the number of horizontal segments, the more precise shape the 3-D structure will define.

FIG. 1A illustrates a tetrahedral structure 10 composed of multiple horizontal segments 115-1, 115-2 . . . 115-(N-1), and 115-N; and FIG. 1B illustrates a spherical structure 120 composed of multiple horizontal segments 125-1, 125-2 . . . 125-(N-1), and 125-N. Horizontal segments 115-1, 115-2 . . . 115-(N-1), and 115-N are stacked one over another to finally form 3-D tetrahedral structure 110; and horizontal segments 125-1, 125-2 . . . 125-(N-1), and 125-N are stacked in a similar fashion to form 3-D spherical structure 120.

Although the 3-D structures illustrated in FIGS. 1A-1B are a tetrahedral structure and a spherical structure, respectively, those skilled in the art will appreciate that any other 3-D structures (e.g., a ladder, a prism, a cylinder, a cone, each solid or hollow, etc.) can be readily fabricated as assemblies of multiple horizontal segments of nano materials. For example, if a desired structure is a ladder, such structure may be assembled with multiple pairs of short rods stacked one over another, a horizontal rod stacked over such pairs and extending between the top pair of the short rods, and repeating the above steps until a ladder of a desired height is obtained. Therefore, any configuration having desired shapes and sizes can be assembled with multiple layered segments using a layer-by-layer construction method.

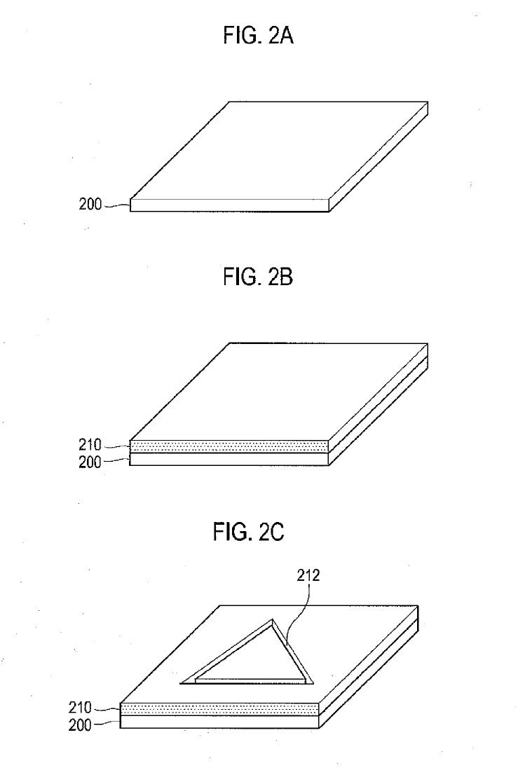

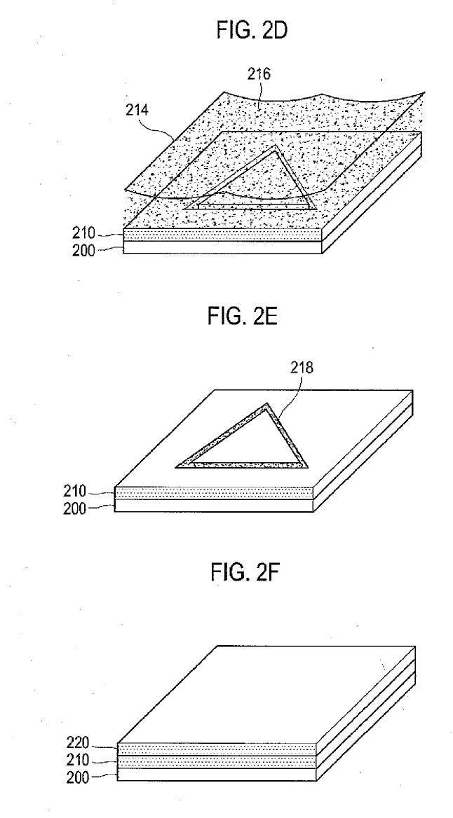

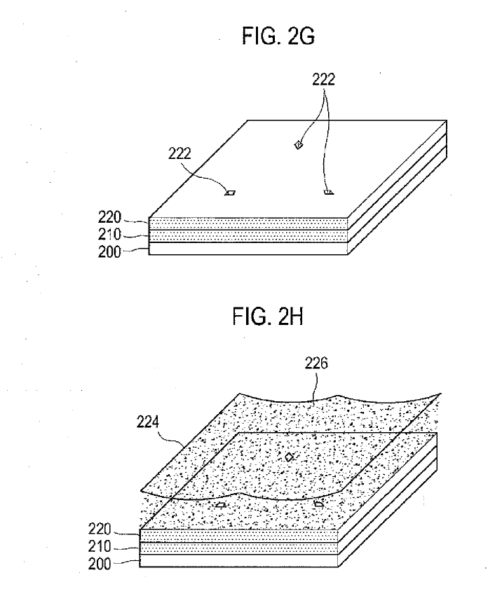

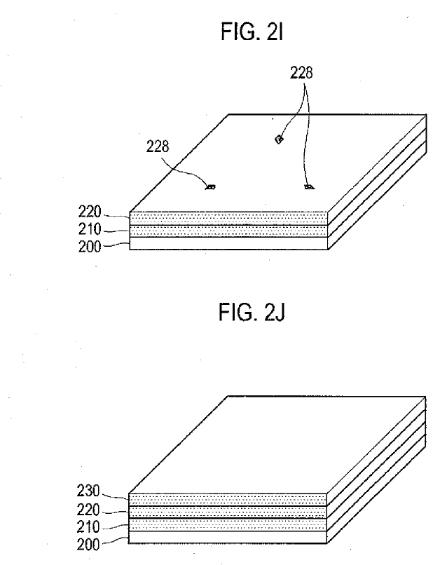

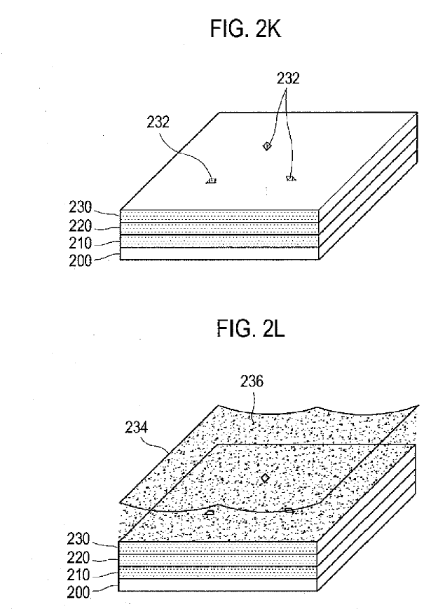

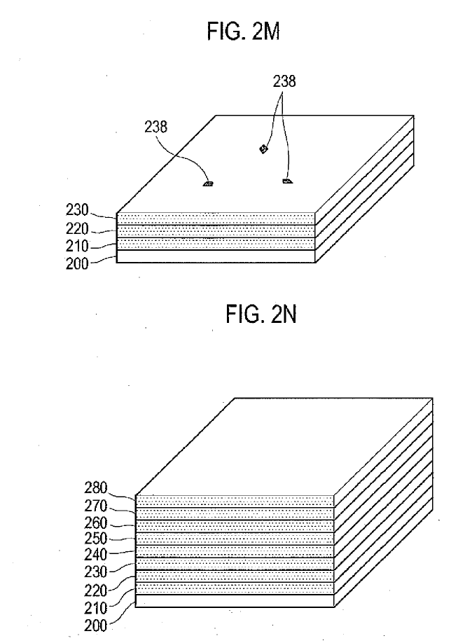

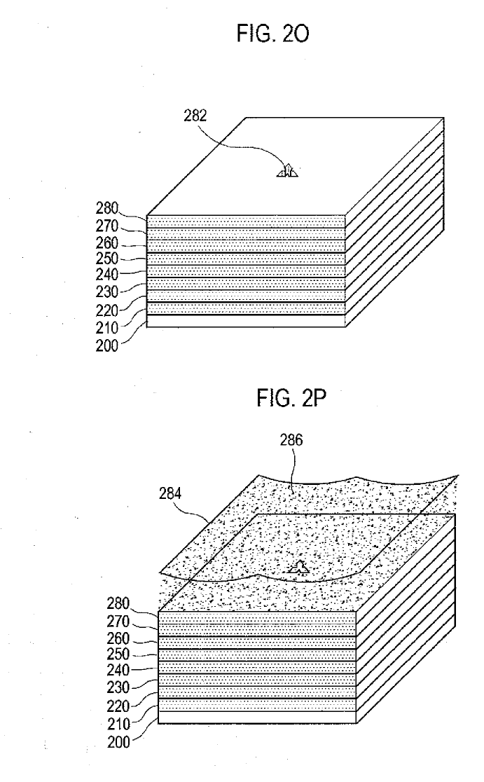

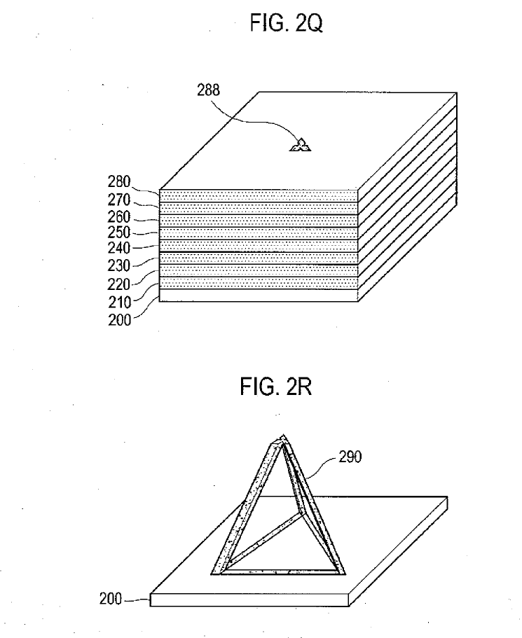

FIGS. 2A to 2R collectively show a process of fabricating a 3-D structure of nano materials in accordance with one embodiment. FIGS. 2A-2R show a process for fabricating a skeleton of a tetrahedral structure such as, e.g., its six sides and four vertices. However, those skilled in the art will appreciate that this process can be applied to manufacturing any other 3-D structures of nano materials. As illustrated in FIG. 2A, a substrate 200 is provided to assemble a 3-D structure of a desired shape and size. Any conventional materials may be used as substrate 200. In one embodiment, substrate 200 may be made of and/or include transparent or semi-transparent (or translucent) materials so that substrate 200 can be used as a display or an optical component while transmitting at least portions of light rays impinging thereon. In another embodiment, substrate 200 may be electrically conductive, semi-conductive or insulative when the resulting structure is to be used as an electronic device. Similarly, substrate 200 may be ferromagnetic, paramagnetic and the like when the resulting structure is to be used in a magnetic device.

By way of example, but not limitation, FIGS. 2A to 2R exemplify a process for assembling a 3-D tetrahedral skeleton structure by stacking eight layers of horizontal segments. Those skilled in the art will appreciate that the 3-D structure to be assembled can be composed of a different number of layered segments, depending on various factors such as the desired height and/or thickness of each layer, just to name a few.

As illustrated in FIG. 2B, a first mask layer 210 may be formed (or deposited) over substrate 200 to a predetermined thickness. In one embodiment, first mask layer 210 may include a photoresist material such as AZ5214E, PMMA (polymethyl-methacrylate), etc.

As illustrated in FIG. 2C, first mask layer 210 is patterned (or etched) to form one or more first grooves 212 corresponding to a first (i.e., base or lower-most) segment of the 3-D structure to be assembled. As depicted, first mask layer 210 is patterned o form a closed groove which corresponds to a first, lower-most segment of the skeleton of a tetrahedron structure, forming a triangle of a predetermined side. In one embodiment, first mask layer 210 may be patterned by photolithography or other equivalent processes.

As illustrated in FIG. 2D, a suspension, emulsion, solution or liquid mixture of nano materials 216 (collectively referred to as a “suspension 214” hereinafter) may be poured on top of first mask layer 210. By way of example, but not limitation, nano materials 216 may be nanotubes, nanowires, other elongated nano materials, quantum dots and the like, where such nano materials 216 may be made of or include carbon, gold, silver, or other conventionally available substances or compounds. Nano materials 216 are to be adsorbed, deposited or otherwise trapped into first groove 212. In some embodiments, the amount of nano materials 216 trapped in first groove 212 may depend on various factors such as the dimension of first groove 212, the length or thickness of nano materials 216, curvature of nano materials 216, and so on. As a result, first groove 212 is filled with nano materials 216 as depicted in FIG. 2E. It is noted that nano materials 216 trapped in first groove 212 may interact with each other and define an aggregate structure or article with desired mechanical integrity. When nano materials 216 do not form such aggregate structure with sufficient mechanical integrity, binders may be added into first groove 212 after trapping nano materials 216 in first groove 212 or, alternatively, deposit nano materials 216 together with binders. Thereafter, the binders may be thermally, mechanically or electrically treated in additional steps to facilitate the formation of an aggregate structure of nano materials 216 with the desired mechanical integrity. The above steps may be carried out in a similar manner for other nano materials, which are to be trapped into grooves for forming other segments of the tetrahedron skeleton structure.

Alternatively, a gas jet device maybe optionally used to eject a stream of gas so as to sweep suspension 214 over first mask layer 210. In this instance, the gas jet may force more nano materials 216 to get into first groove 212 while sweeping away residual suspension 214. Sweeping the top surface of suspension 214 would result in a first nano-material-filled groove 218, as illustrated in FIG. 2E.

Thereafter, as illustrated in FIG. 2F a second mask layer 220 may be formed on top of first filled groove 218 and the rest of first mask layer 210. In one embodiment, second mask layer 220 may include a photoresist material such as AZ5214E, PMMA (polyrnethyl-methacrylate), etc. In another embodiment, second mask layer 220 may include substances different from those used for first mask layer 210. It is appreciated that second mask layer 220 is generally deposited to have the substantially same thickness as first mask layer 210, although mask layers 210, 220 may define different thicknesses due to various factors such as, e.g., mechanical strength, properties of the resulting structure to be assembled, and the like. It is also appreciated that the above embodiments may apply to other mask layers to be disposed on second mask layer 220. As illustrated in FIG. 2C second mask layer 220 may be patterned to form one or more second grooves 222 corresponding to second from bottom segment of the 3-D structure to be assembled. As depicted in FIG. 2G, second mask layer 220 is patterned to form three second grooves 222 which correspond to the bottom segment of three legs of the tetrahedron skeleton and, therefore, are spaced apart from each other by a predetermined distance. In some embodiments, second mask layer 220 may be patterned by photolithography or other equivalent processes.

Thereafter, as illustrated in FIG. 2H, a suspension 224 of nano materials 226 may be poured again on top of second mask layer 220. Nano materials 226 may be adsorbed, deposited or otherwise trapped into each of second grooves 222. Although it may be customary to deposit the same nano materials into second grooves 222, different nano materials may instead be deposited in second grooves 222 so that the resulting tetrahedron skeleton may be composed of different nano materials in different segments. It is appreciated that the above embodiment may be applied to other grooves for forming the other mask layers.

Thereafter, the gas jet device may be optionally used to eject a stream of gas so as to sweep suspension 224 over second mask layer 220. In this instance, the gas jet may force more nano materials 226 to get into second grooves 222 while sweeping away residual suspension 224. Sweeping the top surface of suspension 224 results in second nano-material-filled grooves 228, as illustrated in FIG. 2I.

Next, as illustrated in FIG. 2J, a third mask layer 230 may be formed on top of second filled grooves 228 and the rest of second mask layer 220. In one embodiment, third mask layer 212 may include a photoresist material such as AZ5214E, PMMA (polymethyl-methacrylate), etc.

Thereafter, as illustrated in FIG. 2K, third mask layer 230 may be patterned to form one or more third grooves 232 corresponding to third segment from bottom of the 3-D structure to be assembled. In one embodiment, third mask layer 232 is patterned to form three grooves 222 which correspond to second from bottom segment of three legs of the tetrahedron skeleton and, therefore, are spaced apart from each other by a predetermined distance, which is less than that of the legs of the first segment. In some embodiments, third mask layer 230 may be patterned by photolithography or other equivalent processes.

Next, as illustrated in FIG. 2L, a suspension 234 of nano materials 236 may be poured again on top of third mask layer 230. Nano materials 236 may be adsorbed, deposited or otherwise trapped into each of third grooves 232.

Thereafter, the gas jet device may be optionally used to eject a stream of gas so as to sweep suspension 234 over third mask layer 230. In this instance, the gas jet may force more nano materials 236 to get into third grooves 232 while sweeping away residual suspension 234. Sweeping the top surface of suspension 234 may result in third nano-material-filled grooves 238, as illustrated in FIG. 2M.

The above processes may be repeated after forming a fourth mask layer 240 over third mask layer 230, a fifth mask layer 250 over fourth mask layer 230, a sixth mask layer 260 over fifth mask layer 250, a seventh mask layer 270 over sixth mask layer 260, and then an eighth mask layer 280 over seventh mask layer 270, as illustrated in FIG. 2N.

Then, as illustrated in FIG. 2O, eighth mask layer 280 may be patterned to form one or more eighth grooves 282 corresponding to the eighth and top segment of the 3-D structure to be assembled. In one embodiment, eighth mask layer 280 is patterned to form eighth groove 282 which corresponds to an apex of the tetrahedron skeleton. In some embodiments, eighth mask layer 217 may be patterned by photolithography or other equivalent processes.

Next, as illustrated in FIG. 2P, a suspension 284 of nano materials 286 is poured again on top of eighth mask layer 280. Nano materials 286 may be adsorbed, deposited or otherwise trapped into eighth groove 282. Thereafter, the gas jet device may optionally be used to eject a stream of gasjet so as to sweep suspension 284 over eighth mask layer 280. In this instance, the gas jet may force more nano materials 286 to get into eighth groove 282 while sweeping away residual suspension 284. Sweeping the top surface of suspension 284 results in an eighth nano-material-filled groove 288, as illustrated in FIG. 2Q.

Thereafter, mask layers 210 to 280 may be removed. In some embodiments, mask layers 210 to 280 may be removed by any conventional etching methods such as reactive ion etching (RIE). Such removing process may result in the desired 3-D structure of nano materials, i.e, the skeleton of tetrahedron structure 290 which is mechanically supported by substrate 200, as illustrated in FIG. 2R.

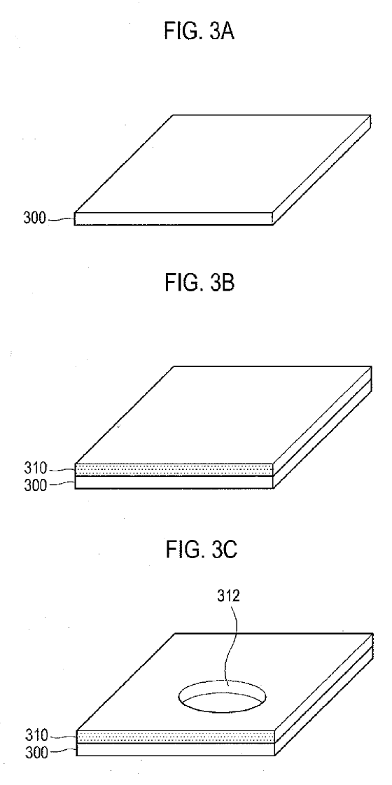

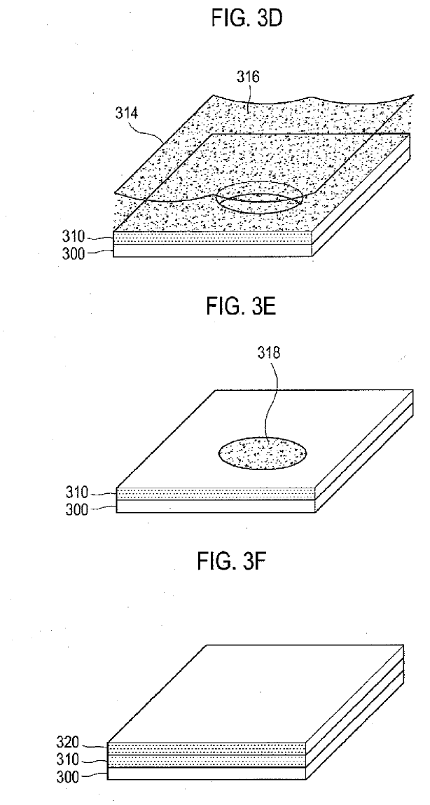

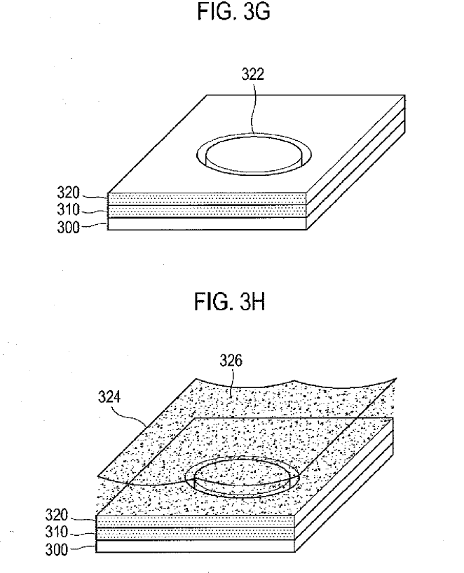

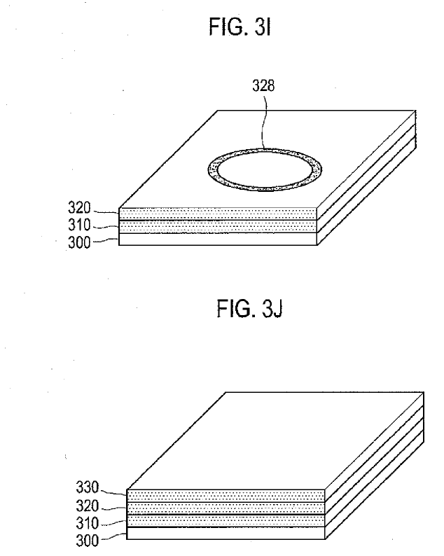

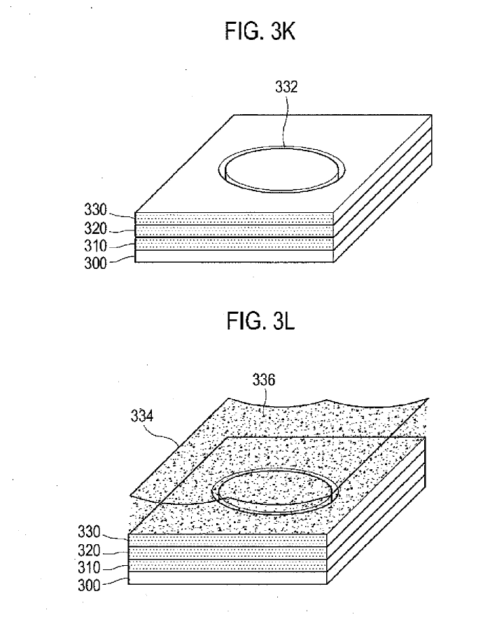

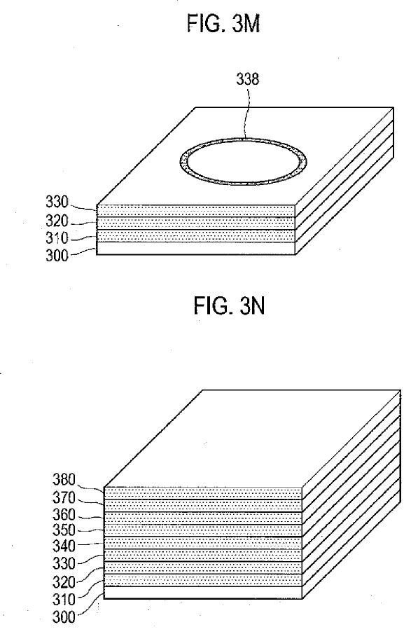

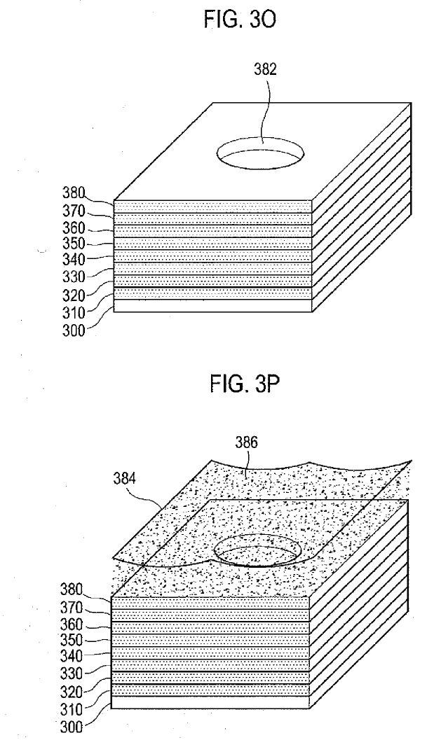

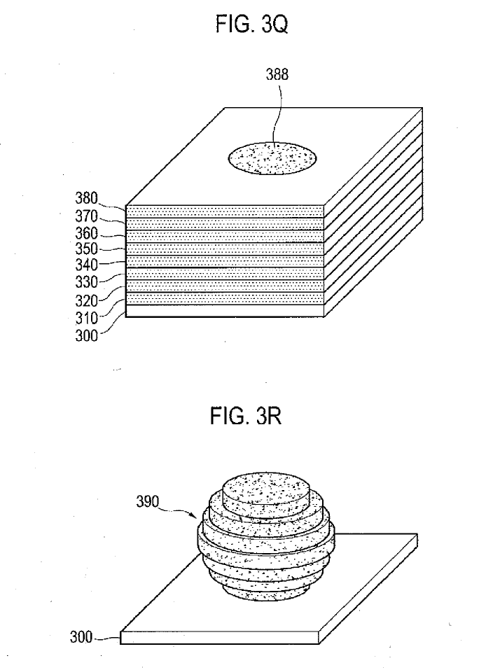

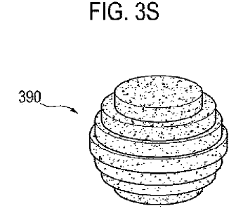

FIGS. 3A to 3S collectively show a process of fabricating a free-standing 3-D structure of nano materials in accordance with another embodiment. Although FIGS. 3A to 3S show a process for fabricating a spherical structure, those skilled in the art will appreciate that this process can be applied to manufacturing any other free-standing 3-D structures of nano materials. It is appreciated that configurational and/or operational characteristics of the structures and methods depicted in FIGS. 3A to 3S are generally similar or identical to those of the structures and methods disclosed in FIGS. 2A to 2R, unless otherwise specified.

As illustrated in FIG. 3A, a substrate 300 is provided to assemble a 3-D structure of a desired shape and size. Any conventional materials (e.g., those disclosed in conjunction with FIG. 2A) may be used as substrate 300. In one embodiment, substrate 300 may include a photoresist material such as AZ5214E, PMMA (polymethyl-methacrylate), etc.

By way of example, but not limitation, FIGS. 3A to 3S exemplify a process for assembling a 3-D hollow spherical structure by stacking eight layers of horizontal segments. Those skilled in the art will appreciate that the 3-D structure to be assembled can be composed of a different number of layered segments, depending on various factors such as the desired height and/or thickness of each layer, just to name a few.

As illustrated in FIG. 3B, a first mask layer 310 may be formed on substrate 300 to a predetermined thickness. In one embodiment, first mask layer 310 may include a photoresist material such as AZ5214E, PEA (polymethyl-methacrylate), etc.

As illustrated in FIG. 3C, first mask layer 310 is patterned (or etched) to form one or more first grooves 312 corresponding to a first (i.e., base or lower-most) segment of the 3-D structure to be assembled. As depicted, first mask layer 310 is patterned to form a round plate which corresponds to a first, lower-most segment of a hollow sphere. In one embodiment, first mask layer 310 may be patterned by photolithography or other equivalent processes.

In some embodiments, the base or bottom segment of the 3-D structure may be arranged to form as little contact with substrate 300 as possible, so as to facilitate detachment of the 3-D structure from substrate 300 when the 3-D structure is completed. In another embodiment, first groove 312 may be formed shallow in first mask layer 310, not to extend all the way through substrate 300, to further facilitate detachment of the 3-D structure from substrate 300.

Next, as illustrated in FIG. 3D, a suspension, emulsion, solution or liquid mixture of nano materials 316 (collectively referred to as “suspension 314” hereinafter) maybe poured on top of first mask layer 310. By way of example, but not limitation, nano materials 316 may be nanotubes, nanowires, other elongated nano materials, quantum dots and the like, where such nano materials 316 may be made of or include carbon, gold, silver, or other conventionally available substances or compounds. Nano materials 316 are to be adsorbed, deposited or otherwise trapped into first groove 312. In some embodiments, the amount of nano materials 316 trapped in first groove 312 may depend on various factors such as the dimension of first groove 312, the length or thickness of nano materials 316, curvature of nano materials 316, and so on. As a result, first groove 312 is filled with nano materials 316 as depicted in FIG. 3E. It is noted that nano materials 316 trapped in first groove 312 may interact with each other and define an aggregate structure or article with desired mechanical integrity. When nano materials 316 do not form such aggregate structure with sufficient mechanical integrity, binders may be added into first groove 312 after trapping nano materials 316 in first groove 312 or, alternatively, deposit nano materials 316 together with binders. Thereafter, the binders may be thermally, mechanically or electrically treated in additional steps to facilitate the formation of an aggregate structure of nano materials 316 with the desired mechanical integrity. The above steps may be carried out in a similar manner for other nano materials, which are to be trapped into grooves for forming other segments of the spherical structure.

Alternatively, the gas jet device may be optionally used to eject a stream of gas so as to sweep suspension 314 over first mask layer 310. In this instance, the gas jet may force more nano materials 316 to get into first groove 312 while sweeping away residual suspension 314. Sweeping the top surface of suspension 314 would result in a first nano-material-filled groove 318, as illustrated in FIG. 3E.

Thereafter, as illustrated in FIG. 3F, a second mask layer 320 may be formed on top of first filled groove 318 and the rest of first mask layer 310 In one embodiment, second mask layer 320 may include a photoresist material AZ5214E, PMMA (polymethyl-methacrylate), etc. In another embodiment, second mask layer 320 may include substances different from those used for first mask layer 310. It is appreciated that second mask layer 320 is generally deposited to have the substantially same thickness as first mask layer 310, although mask layers 310, 320 may define different thicknesses due to various factors such as, e.g., mechanical strength, properties of the resulting structure to be assembled, and the like. It is also appreciated that the above embodiments may apply to other mask layers to be disposed on second mask layer 320.

As illustrated in FIG. 3C second mask layer 311 may be patterned to form one or more second grooves 322 corresponding to second from bottom segment of the 3-D structure to be assembled. As depicted in FIG. 3G, second mask layer 320 is patterned to form an annular ring 322 which corresponds to a second (from bottom) segment of a hollow spherical structure. The thickness of annular ring 321 may correspond to the wall thickness of the sphere to be assembled. In one embodiment, second mask layer 320 may be patterned by photolithography or other equivalent methods.

Next, as illustrated in FIG. 3H, a suspension 324 of nano materials 326 may be poured again on top of second mask layer 320. Nano materials 326 may be adsorbed, deposited or otherwise trapped into each of second grooves 322. Although it may be customary to deposit the same nano materials into second grooves 322, different nano materials may instead be deposited in second grooves 322 so that the resulting hollow spherical structure may be composed of different nano materials in different segments. It is appreciated that the above embodiment may be applied to other grooves for forming the other mask layers.

Thereafter, the gas jet device may optionally eject a stream of gas jet so as to sweep suspension 324 over second mask layer 320. In this instance, the gas jet may force more nano materials 326 to get into second groove 322 while sweeping away residual suspension 324. Sweeping the top surface of suspension 324 results in second nano-material-filled groove 328, as illustrated in FIG. 3I.

Next, as illustrated in FIG. 3J, a third mask layer 330 may be formed on top of second filled grooves 328 and the rest of second mask layer 320. In one embodiment, third mask layer 312 may include a photoresist material such as AZ5214E, PMMA (polymethyl-methacrylate), etc.

Thereafter, as illustrated in FIG. 3K, third mask layer 330 may be patterned to form one or more third grooves 332 corresponding to a third segment from bottom of the 3-D structure to be assembled. In one embodiment, third mask layer 330 is patterned to form another annular ring 322 which corresponds to third from bottom segment of the hollow spherical structure. In some embodiments, third mask layer 330 may be patterned by photolithography or any other equivalent methods.

Next, as illustrated in FIG. 3L, a suspension 334 of nano materials 336 may be poured again on top of third mask layer 330. Nano materials 336 may be adsorbed, deposited or otherwise trapped into each of third grooves 330.

Thereafter the gas jet device may be optionally used to eject a stream of gas so as to sweep suspension 334 over third mask layer 330. In this instance, the gas jet may force more nano materials 336 to get into third grooves 332 while sweeping away residual suspension 334. Sweeping the top surface of suspension 334 may result in third nano-material-filled grooves 338, as illustrated in FIG. 3M.

The above processes may be repeated after forming a fourth mask layer 340 over third mask layer 330, a fifth mask layer 350 over fourth mask layer 340, a sixth mask layer 360 over fifth mask layer 350, a seventh mask layer 370 over sixth mask layer 360, and then an eighth mask layer 380 over seventh mask layer 370, as illustrated in FIG. 3N.

Then, as illustrated in FIG. 3O, eighth mask layer 380 may be patterned to form one or more eighth grooves 382 corresponding to the eighth and upper most segment of the 3-D structure to be assembled. In one embodiment eighth mask layer 380 is patterned to form eighth groove 382 which corresponds to the upper-most portion of a sphere. In one embodiment, eighth mask layer 317 may be patterned by photolithography or other equivalent methods.

Next, as illustrated in FIG. 3P, a suspension 384 of nano materials 386 is poured again on top of eighth mask layer 380. Nano materials 384 may be adsorbed, deposited or otherwise trapped into eighth groove 382.

Thereafter the gas jet device may be optionally used to eject a stream of gas jet so as to sweep suspension 384 over eighth mask layer 380. In this instance, the gas jet may force more nano materials 386 to get into eighth groove 382 while sweeping away residual suspension 384. Sweeping the top surface of suspension 384 results in an eighth nano-material-filled groove 388, as illustrated in FIG. 3Q.

Thereafter mask layers 310 to 380 may be removed. In one embodiment, mask layers 310 to 380 may be removed by any conventional etching methods such as reactive ion etching (RIE). Such removing process may result in the desired 3-D structure of nano materials, a hollow spherical nano structure 390, attached to substrate 300, as illustrated in FIG. 3R.

Spherical nano structure 390 attached to substrate 300 may be further processed to form a free-standing structure 390 as illustrated in FIG. 3S. In one embodiment, substrate 300 may be removed by conventional etching method or other equivalent methods. It is appreciated that that the substrate 300 may be removed either at the time of removing the mask layers 310 to 380 or after removing mask layers 3 10 to 380. Alternatively, nano structure 390 may be pressed against another article which tends to adhere to structure 390. By facilitating the detachment of nano structure 390 from substrate 300, nano structure 390 may be stamped onto another article which may then be used for various applications.

Spherical nano structure 390 of FIG. 3S can be used for various applications. By way of example, but not limitation, the structure may be utilized as a light emitting element when the segmented nano materials can emit light rays in response to electric voltage or current. The structure may also be used as a sensor which can monitor various chemical, electrical, magnetic or optical inputs of a sample.

It is appreciated that the above processes for fabricating the 3-D structure of nano materials may be performed utilizing any substrate and photoresists as long as such materials can conform to the above processes. The nano materials may also be any nano materials of which aspect ratios are greater than, e.g., 20, 50, 100, 1000, or even 10000. Alternatively, the nano materials used may be particles such as quantum dots. Regardless of the shapes and sizes of the nano materials, suitable binding materials may also be used to enhance mechanical integrity of the resulting nano structure. The photoresists and/or substrate may also be patterned or removed by various conventional lithographic or etching methods. In general, selection of such materials and lithographic methods is generally well known to those of ordinary skill in the relevant art such as, e.g., semiconductor processing, MEMS processing, and nano technology.

As set forth herein, the 3-D structures of various nano materials are required to exhibit at least minimal mechanical integrity. It is generally appreciated that the nano materials of the aggregate hold each other by physical interaction therebetween and that such interaction may not be sufficient to provide the mechanical integrity to the structure. In such a case, the nano materials may be physically coupled to each other by other binders. By way of example, but not limitation, such binders may be electrical conductors when desired. In one embodiment, such binders may be incorporated after the entire 3-D structure is formed. In another embodiment, the binders may be incorporated whenever each segment is formed.

The above structures may be used as electronic or optical components by themselves or as parts of a more complicated electronic or optical device. Because the above method allows fabrication of the 3-D structure of any arbitrary shapes and sizes, such a structure may find its use wherever various mechanical, electrical, or optical properties of a specific nano material is useful.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A method for manufacturing a 3-D structure of nano materials resembling a target structure, comprising:
approximating a preset target structure as a stack of a plurality of segments of the 3-D structure of nano materials;
providing a substrate;
forming a mask layer;
patterning the mask layer to form one or more grooves corresponding to one of the segments of the 3-D structure;
filling the grooves with the nano materials;
repeating the forming, patterning and filling above for the remaining segments; and
removing the mask layers, whereby obtaining the 3-D structure void of the mask layers.

2. The method of claim 1, further comprising removing the substrate.

3. The method of claim 1, wherein filling the grooves comprises adsorbing or depositing the nano materials into the grooves.

4. The method of claim 1, wherein filling the grooves comprises pouring a suspension, emulsion, solution or liquid mixture including the nano materials on the mask layer.

5. The method of claim 4, wherein filling the grooves further comprises sweeping the suspension, emulsion, solution or liquid mixture over the mask layer.

6. The method of claim 5, wherein sweeping comprises ejecting a stream of gas thereto.

7. The method of claim 1, wherein the 3-D structure is a shape selected from the group consisting of a tetrahedron, a sphere, a cone, a cube and a ladder.

8. The method of claim 1, wherein the nano materials includes at least one of a nano element including nanotubes, nanowires and quantum dots and wherein the nano element is made of at least one of carbon, silver and gold.

9. The method of claim 1, wherein the substrate comprises transparent or semi-transparent materials.

10. The method of claim 1, wherein the mask layer comprises a photoresist material.

11. The method of claim 1, wherein patterning the mask layer is carried out by photolithography.

12. The method of claim 1, wherein removing the mask layer is carried out by etching.

13. The method of claim 1, further comprising incorporating binders into the nano materials for providing mechanical integrity to the 3-D structure.
